(19) United States
(12) Patent Application Publication
(10) Pub. No.: US 2014/0015594 A1
(43) Pub. Date: Jan. 16, 2014

(54) SWITCHING CELLS USING MOSFET POWER TRANSISTORS

(71) Applicants: Antonino Fratta, Torino (IT); Paolo Guglielmi, Torino (IT); Eric Giacomo Armando, Costigliole Saluzza (Cuneo) (IT)

(72) Inventors: Antonino Fratta, Torino (IT); Paolo Guglielmi, Torino (IT); Eric Giacomo Armando, Costigliole Saluzza (Cuneo) (IT)

(73) Assignee: ET99 S.R.L., Torino (IT)

(21) Appl. No.: 14/008,405

(22) PCT Filed: Mar. 14, 2012
(86) PCT No.: PCT/IB12/51195

§ 371 Date: Sep. 27, 2013

(30) Foreign Application Priority Data
Mar. 29, 2011 (IT) TO2011A000280

(51) Int. Cl. H03K 17/687

(52) U.S. Cl. CPC H03K 17/687
USPC 327/434

(57) ABSTRACT

The switching cell (1), comprises, between the terminals of a supply source (2) supplying a voltage (VC), a controlled power switch (T) and a current recirculation device (CRD) including a diode or a junction, between which there is defined a common terminal (O) of the cell (1).

Across the current recirculation device (CRD) there are connected controlled electric charge supply means (TL, VL, DL; TH, VH, DH) comprising
a first generator circuit (TL, VL, DL) for generating a low voltage, including a first d.c. voltage source (VL), an associated first controlled switch (TL), and a first diode (DL), and adapted to supply an electric charge sufficient to cause the reverse-recovery of the current recirculation device (CRD); and
a second generator circuit (TH, VH, DH) for generating a higher voltage, including a second d.c. voltage source (VH), an associated second controlled switch (TH) and a second diode (DH) having a lower capacitance than that of the first diode (DL), and adapted to inject into the recirculation device (CRD) an amount of electric charge (QD) which varies in a non-linear manner as a function of the voltage, and also to deliver an amount of electric charge sufficient to cause the first diode (DL) to be cut off when the first controlled switch (TL) is closed.

The present invention relates in a general way to a controlled switching cell.

More specifically, the invention relates to a controlled switching cell of the type defined in the preamble of claim 1.

A switching cell of this type is described in A. Fratta and others, “Commutation losses reduction in high voltage power MOSFETs by proper commutation circuit”, 2011 IEEE International Conference on Industrial Technology, 15 Mar. 2011, pages 127-132, XP 55009345, D01: 10.1109/ICIT.2011.5754359, ISBN: 978-1-42-449064-6.

In general, the invention relates to design methods and circuit means required to use a switching cell of this type, controlled at a high switching frequency, with minimal energy losses, despite the parasitic dynamic phenomena (the dual nature of which is examined below) of the most efficient recirculation devices in current conduction.

In particular, some power devices for high voltages have characteristic parasitic capacitances, which vary in a non-linear way with voltage, and which have dissipative effects which are less well-known but not negligible, being similar to those of the well-known phenomenon of “reverse recovery” which is typical of semiconductor junction diodes, although this is caused by fundamentally different phenomena.

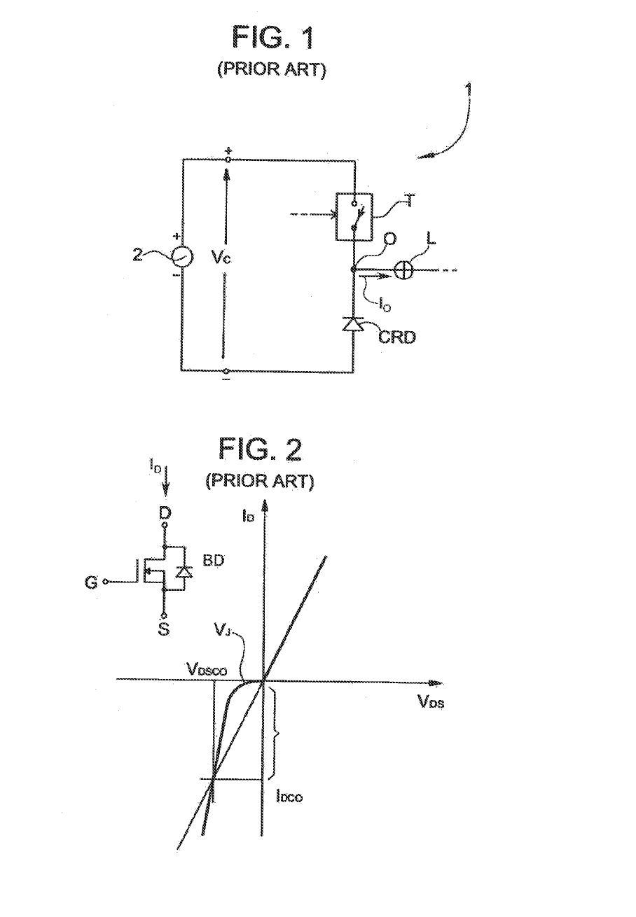

A prior art controlled switching cell is shown in FIG. 1 of the attached drawings, where it is indicated as a whole by the number 1. In this drawing, the number 2 indicates a source adapted to deliver a d.c. voltage V_{c}. Between the terminals of the source 2 there are connected a controlled switch T, such as a transistor, and a current recirculation device CRD, in particular a diode having its anode connected to the negative terminal of the source 2 and its cathode connected to the controlled switch T.

The connection between the switch T and the recirculation device CRD, indicated by O, forms the common terminal of the cell 1, for connection to an inductive circuit L through which the (output) current I_{O} flows. An inductive circuit L of this type can generally be considered as a current generator, at least during the brief time intervals in which the switching of the cell 1 takes place.

According to the prior art, recirculation devices are characterized by non-ideal dynamic behaviour which dominates their switching off, which is normally forced by the closing of the switch T of the cell (1 in FIG. 1).

In the case of semiconductor junction diodes, the phenomenon which is referred to as a whole as “reverse recovery”, is primarily dominated by the time delay (“storage time”) during which the diode behaves as an excellent conductor, although conducting reverse current. This delay is highly dependent on the temperature and on the current (reverse as well as direct) which was conducted before switching.

In the case of a Schottky diode, this phenomenon does not occur in theory, but it is known that a certain amount of reverse charge has to be “forced” in order to cut off the diode, although this is theoretically independent of temperature and current.

The phenomena described above, which are capacitive in nature, are caused by parasitic capacitances which vary greatly with the voltage applied between the cathode and anode of the recirculation device.

In general, both of the above phenomena, although completely different in nature, are in fact characteristic of recirculation devices, particularly the most efficient ones in the prior art and in new technology.

For example, for very low-voltage applications, instead of a simple diode the current recirculation device CRD of cell 1 in FIG. 1 is replaced by a MOSFET transistor, whose so-called intrinsic diode, or “body diode”, is used, at least in a transient way. However, this solution is not used in high-voltage applications: as the operating voltage rises, the intrinsic diode of a MOSFET transistor becomes increasingly “slow”, and in particular the switching losses increase when compared with the use of ultra-fast diodes.

However, the use of MOSFETs as synchronous rectifiers (abbreviated to “SR” hereafter) provides an example demonstrating the properties of efficiency expected from new technologies, together with the switching problems which must be overcome in order to achieve high overall efficiency in practice.

FIG. 2 of the attached drawings shows in a qualitative way the intrinsic conduction characteristics of a MOSFET transistor, in the form of a correlation between the drain current I_{D} and the drain-source voltage V_{DS}.

In the first quadrant (where I_{D} and V_{DS} are positive), a MOSFET operates as a transistor: FIG. 2 shows only the conduction characteristic, called “resistive” because it is essentially proportional in nature.

In the third quadrant (where I_{D} is positive and V_{DS} is negative), there is a continuation of this “resistive” characteristic, which is an exclusive property of MOSFETs. In practice, however, it cannot be utilized as variable conductivity, owing to the conduction of the intrinsic diode (body-diode) BD in parallel with the controllable resistive conduction channel of the MOSFET. In the third quadrant, therefore, the MOSFET can only be operated as a diode, with conduction drops partially controllable in the downward direction, by controlling the MOSFET in conduction:
for values of V_{DS} between zero and V_{J} (the threshold voltage of the junction of the intrinsic diode), the current flowing in the intrinsic diode BD is considered to be negligible, but there is no evidence that the reverse recovery charge correlated with the conduction of the negligible current can also be disregarded;
for negative values of V_{DS} which are higher than V_{J} in absolute terms, the current in the intrinsic diode BD is in any case non-negligible; in such circumstances, the reverse recovery phenomenon is dominant in switching.

In the first range of values of V_{DS}, the MOSFET theoretically acts as an SR (synchronous rectifier), providing the dual benefits, in theory, of a substantially smaller voltage drop (and power loss) than that of a junction diode, together with the theoretical possibility of avoiding the dynamic effects (reverse recovery) inherent in the restoration of the cut-off state of the intrinsic diode BD which has previously been a current conductor.

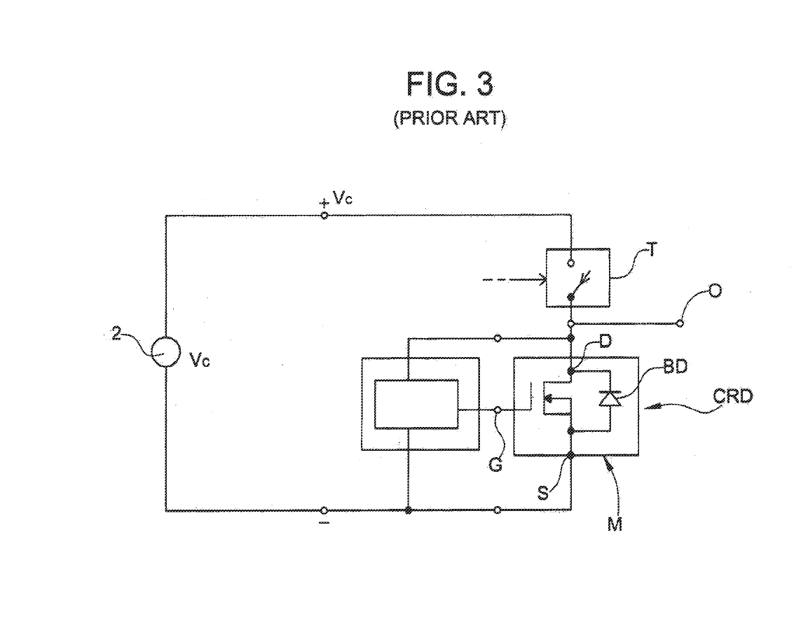

For very low-voltage applications, for example in power supplies for CPUs with output voltages of a few volts, switching cells of the type shown in FIG. 3 are used in the prior art, these cells being implemented with two MOSFETs, one of which is used to form the power switch T while the other is used as a controlled recirculation device CRD, driven in synchronous mode, in other words as an SR. These MOSFETs are controlled by means of integrated driver circuits capable of reliably providing the necessary synchronization between the (complementary) conduction states of the two MOSFETs used.

For higher-voltage applications (above 50 V, and even up to 1000 V or more, with silicon carbide (SiC) semiconductors), the implementation of this principle is purely hypothetical at the present time and has not been achieved in practice. The problems associated with such implementation are difficult to resolve, and some of them have been found to have an increasing impact with a rise in voltage, as follows:
the driver circuits cannot be integrated, or at least are much more costly and subject to greater and more uncertain delays;
the resistivity of the MOSFETs increases in a way which is more than proportional to the nominal voltage, and therefore their operation as SRs must be limited to currents considerably below the nominal level;
the resistance of the MOSFET channel increases with the operating temperature, whereas the threshold voltage of the intrinsic diode decreases, and any application of the characteristics of the MOSFET without allowance for the conduction of the intrinsic diode is therefore impractical and unreliable.

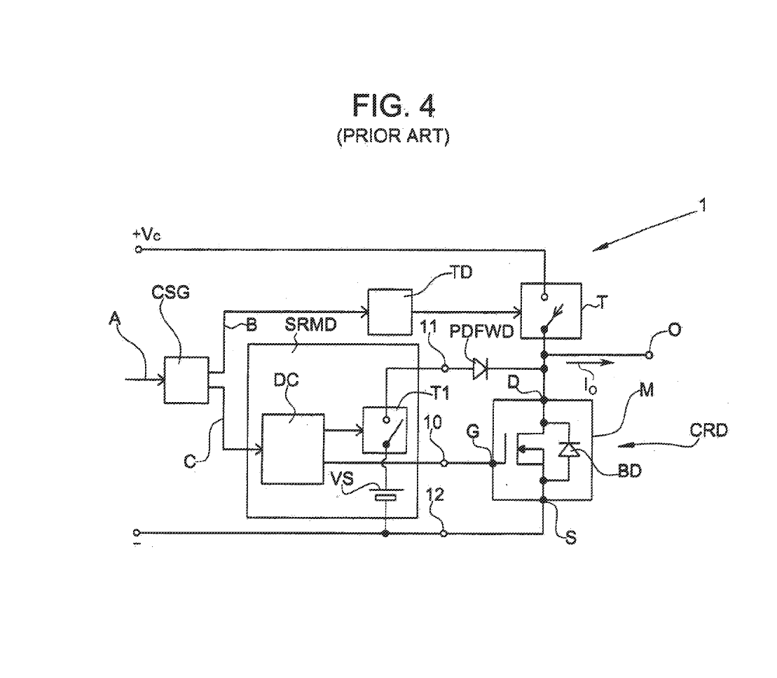

According to a known principle (disclosed, for example, in the preceding Italian patent application TO2010A000822 in the name of the present applicant), shown schematically in FIG. 4 of the attached drawings, it is considered that the aforesaid problems of the application of MOSFETs as SRs can be resolved by using driver circuits which have a generic low-voltage power supply VS, a low-voltage controlled switch T1 and a high-voltage diode PDFWD, and which are capable of reverse biasing the body diode BD of the CRD (SR) before the operation of closing the controlled switch T, thus limiting the energy dissipation thereof.

If we consider the undesirable effects of the application of the idea for a solution shown in FIG. 4, certain significant cases can be identified, as follows:
the diode PDFWD is of the junction type, and therefore exhibits the phenomenon of reverse recovery, or is of the Schottky type, for example a silicon carbide (SiC) diode, but with a low voltage drop and therefore a large area and consequently a high parasitic capacitance;
the diode PDFWD is a series of low-voltage Schottky diodes, or one high-voltage Schottky diode, such as an SiC diode, designed with a reduced area to reduce the costs and phenomena of parasitic capacitance, and therefore with a high voltage drop at the output current (Jₒ), and the voltage of the generator (VS) is of the order of magnitude of a few volts or tens of volts, available when the MOSFETs are driven in the normal way.

In both cases, there are switching losses in T which, although reduced, are too high to justify the cost, the complexity and the energy absorbed by the driver circuit. In the second case in particular, it is found that the switching loss in T can decrease to very satisfactory minimum values as the voltage of VS rises, but clearly the corresponding driver circuit SRMD becomes more costly and the energy absorbed by VS is far from negligible.

These unsatisfactory results are due to the diverse and dual nature of the parasitic phenomena which impede the cut-off of an efficient recirculation device: firstly, the known phenomenon of reverse recovery requires a very high level of charge to cause the state of very good electrical conduction to cease (storage time); secondly, there are other non-negligible effects, of varying nature and quantity, due to the less well-known phenomenon of the charge displacement required to initiate the reverse biasing of the diode and the controlled switches. In particular, all MOSFETs, and especially those of the “trench gate” type designed for high voltages and having very low resistivity, are characterized by non-constant parasitic capacity, which increases (possibly by two orders of magnitude) when the voltage V_{DS} is reduced to zero.

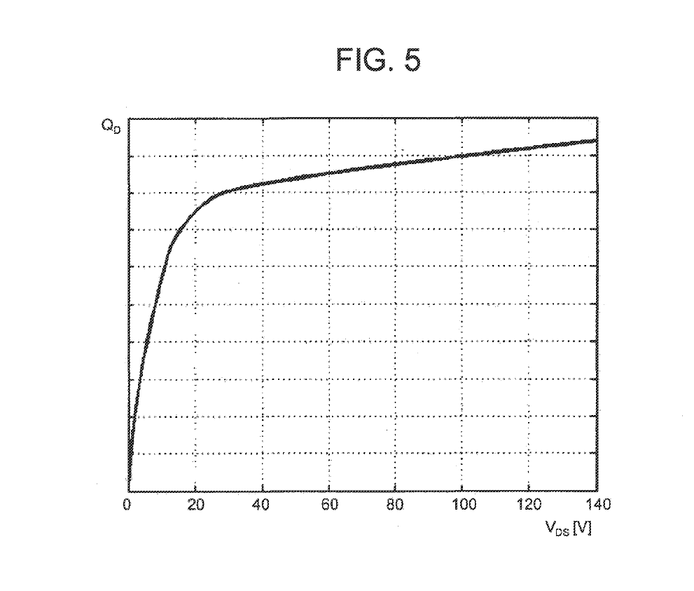

The essential characteristics of these non-linear capacitive phenomena are summarized in the graph of FIG. 5, plotted on the basis of experimental findings for a high-voltage MOSFET which can be used as an SR: the horizontal axis shows the voltage V_{DS}, re-applied to the SR after the conduction of zero current, in other words when it is certain that there can be no phenomenon of reverse recovery of the body diode; the vertical axis shows the integral of the drain current, in other words the quantity of charge QD(VDS) displaced in order to re-apply the voltage V_{DS}. This graph reveals the presence of very high non-linearity, similar to a discontinuity, of the parasitic capacitive behaviour which in fact has an effect on the electromagnetic compatibility of switching. This parasitic charge Q_{D} corresponds to high energy losses in the operation of closing the controlled power switch

T, similar to what is known to be caused by reverse recovery, although having radically different origins and characteristics. Indeed, in order to demonstrate the efficacy of the invention, the graph of FIG. 5 shows that a voltage V_{DS} greater than tens of volts is required in order to supply this non-linear parasitic charge Q_{D} from an external circuit. This quantity should be compared with the few volts which may be sufficient to supply the reverse recovery, particularly for the purpose of conducting in the diode the quantity of reverse “storage” charge required to cause the termination of the reverse conductor state.

In conclusion, it may be stated that a circuit for supplying these charges does not represent a solution of the problem of cutting off recirculation devices.

Other solutions have been proposed, characterized by a substantial assistance to switching obtained by the controlled application of a low voltage through inductances, possibly in combination with capacitors (snubbers), to provide theoretically efficient resonant switching. However, these solutions give rise to various problems of cost and overall dimensions for the additional active and reactive components, and of constraints on the minimum delays required for the correct execution of the successive switching operations.

As will be more clearly apparent from the following text, the principles on which the invention is based can be summarized thus, for any high-efficiency recirculation device in high-voltage applications:
for the efficient and reliable conduction of a recirculation device, it is also essential to allow for the conduction of junction diodes with a low voltage drop (for example, the body diodes of MOSFETs) in order to reduce the conduction losses and the costs, in quantity and quality, of the semiconductor used; and
the circuits added for this purpose have energy costs and losses which can be justified only if all forms of dynamic imperfection of the recirculation devices with low conduction drop are resolved in a highly efficient way.

The invention proposes solutions having minimum cost and maximum efficiency and reliability, based on a strictly predetermined time sequence of activation of circuits differentiated in the quality of the components and quantity of the electrical quantities in use.

The object of the present invention is therefore to propose a solution for producing a controlled switching cell operating in conditions of very high efficiency, using a current recirculation device which is highly efficient in conduction, in other words with voltage drops smaller than those found in an ordinary ultra-fast junction diode, but without suffering from the effects of the reverse recovery phenomenon or from the effects of non-linear parasitic capacitive phenomena.

A related and consequential object is to allow for the optimal use of a cell in which a MOSFET is used as an SR, enabling full use to be made of the current rating of the MOSFET, and thus enabling the MOSFET to operate in high voltage conditions as an SR, permitting the conduction of the intrinsic diode.

A further object of the present invention is to enable optimal use, in cost terms, to be made of the MOSFET transistor which is used for current recirculation, by means of a solution which also provides for the creation of what are known as inverter legs or bidirectional cells, with only two MOSFET transistors operating alternately as controlled power switches and synchronous rectifiers for current recirculation, as a function of the sign of the current in the circuit connected to the common terminal of the cell.

These and other objects are achieved according to the invention with a unidirectional current controlled switching cell whose salient characteristics are defined in claim 1.

In a cell of this type, a controlled switch, also called a power switch, and a current recirculation device, characterized by a quantity of parasitic charge varying in a non-linear way as a function of the voltage across the device, are connected between the terminals of a d.c. voltage source. A common terminal of the cell is formed between the controlled switch and the recirculation device. The current recirculation device exhibits both efficiency in conduction and an inefficient switching dynamic due to the phenomena of reverse recovery and non-linear parasitic capacitance, and the switching cell comprises differentiated means, connected across the recirculation device, for the efficient controlled supply of the quantities of charge required by the different parasitic phenomena.

These differentiated means comprise:
a first, low-voltage, generator circuit, including a first d.c. voltage source and an associated first controlled switch, supplying a first “fast” diode, in other words a diode for operation at high switching frequency, which may or may not be of the junction type, but which is capable of conducting very high pulsed current levels with a low voltage drop, thus rapidly conducting the electrical storage charge required to force the reverse recovery of the recirculation device, this charge being supplied by the first generator circuit, characterized by a low voltage, of a few volts for example; and
a second, higher-voltage, generator circuit, which includes a second d.c. voltage source and an associated second controlled switch, and which supplies a second diode preferably having a lower capacitance than that of the recirculation device and a negligible reverse recovery phenomenon, for example a Schottky diode, or a plurality of low-voltage diodes in series, for injecting a quantity of non-linear parasitic charge into the recirculation device of the cell, and for simultaneously supplying a sufficient quantity of charge to cut off the first diode when the first controlled switch is closed, these quantities of electrical charge being supplied by the second generator circuit, characterized by a higher voltage, for example a few tens of volts, required to supply the non-linear charge to the recirculation device.

According to one characteristic of the invention, the controlled switch of the second voltage generator circuit must be closed no earlier than the end of the phenomenon of the charge storage in the recirculation device, and the power switch of the cell must be closed immediately thereafter, thus minimizing the consumption of the energy absorbed by the first and second generator circuits and the energy dissipated in the power switch.

According to another characteristic, applicable in a general way to power recirculation devices, the controlled switches of the first and second voltage generators are controlled by a single control signal, the first controlled switch, which supplies the charge for storage, being closed in direct dependency on the single control signal, the second controlled switch being controlled to close immediately after the end of the storage, in other words after the end of the reverse conduction state of the current recirculation device.

The discontinuity of reverse conduction is conveniently detected in feedback mode by an electrical potential measurement and comparison circuit, particularly on at least one of the terminals of the recirculation device in common with the first and second switched voltage generator circuits. Thus this measurement and comparison circuit can control the controlled switch of the second switched generator circuit at low cost, with a negligible delay following the end of the reverse conduction state or storage state of the current recirculation device.

According to a further characteristic, the circuit for measuring and comparing the voltage across the current recirculation device generates a logical control signal which is transmitted to the control and modulation unit of the switching cell, in such a way that the controlled power switch of the switching cell is driven to close with a predetermined delay following the instant at which the measurement and comparison circuit detects the end of the storage phenomenon and transmits a corresponding signal, thus cutting off the diode of the second voltage generator circuit, and therefore limiting the operating time and the energy absorption of the second switched voltage generator circuit.

According to a further characteristic, limited to the case in which a MOSFET is used as an SR and therefore as a current recirculation device of a switching cell, the aforesaid first and second voltage generator circuits are coupled to the drain and source terminals of this MOSFET, and therefore of its body diode, the aforesaid first and second voltage generators and the circuit for measuring and comparing the voltage between the drain and source all being referred to the source terminal of the MOSFET (SR), and therefore being capable of integration into a single circuit comprising the gate control circuit for the MOSFET.

Further characteristics and advantages of the invention will be made clear by the following detailed description, provided purely by way of non-limiting example, with reference to the appended drawings, in which:

FIG. 1, described above, is a circuit diagram of a standard unidirectional current switching cell of a known type;

FIG. 2, also described above, shows theoretical characteristics of a MOSFET transistor;

FIG. 3, also described above, is a circuit diagram, partially in block form, of a prior art controlled switching cell;

FIG. 4 is a circuit diagram, described above, of a unidirectional current switching cell operating on a known principle;

FIG. 5, also described above, shows the phenomenon of voltage dependent parasitic capacitance, in terms of quantity of charge displaced with a rise in voltage applied to an efficient current recirculation device;

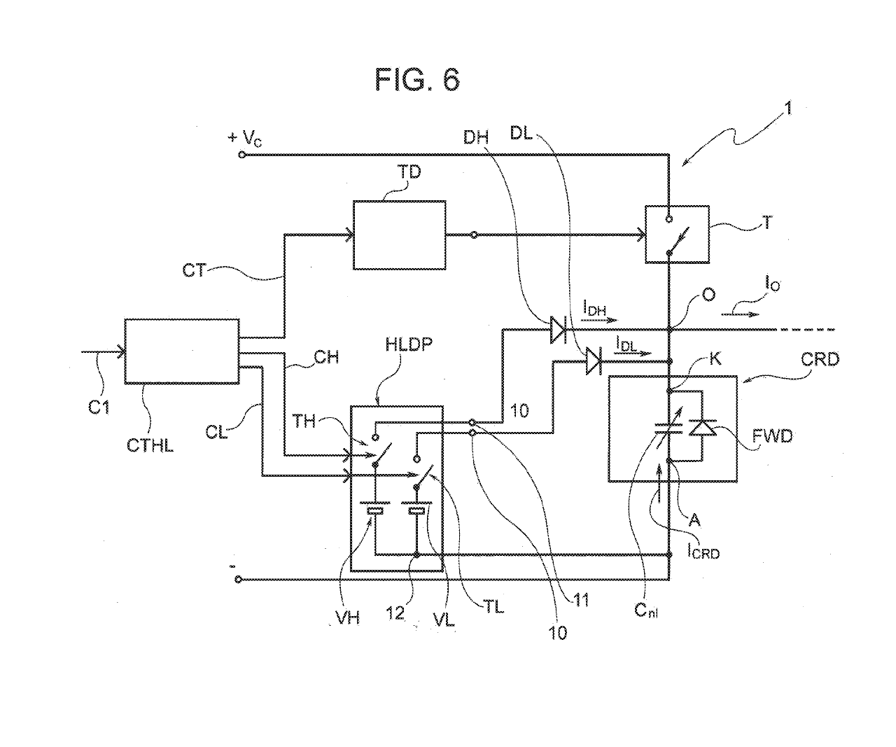

FIG. 6 is a circuit diagram, partially in block form, of a unidirectional switching cell according to the invention;

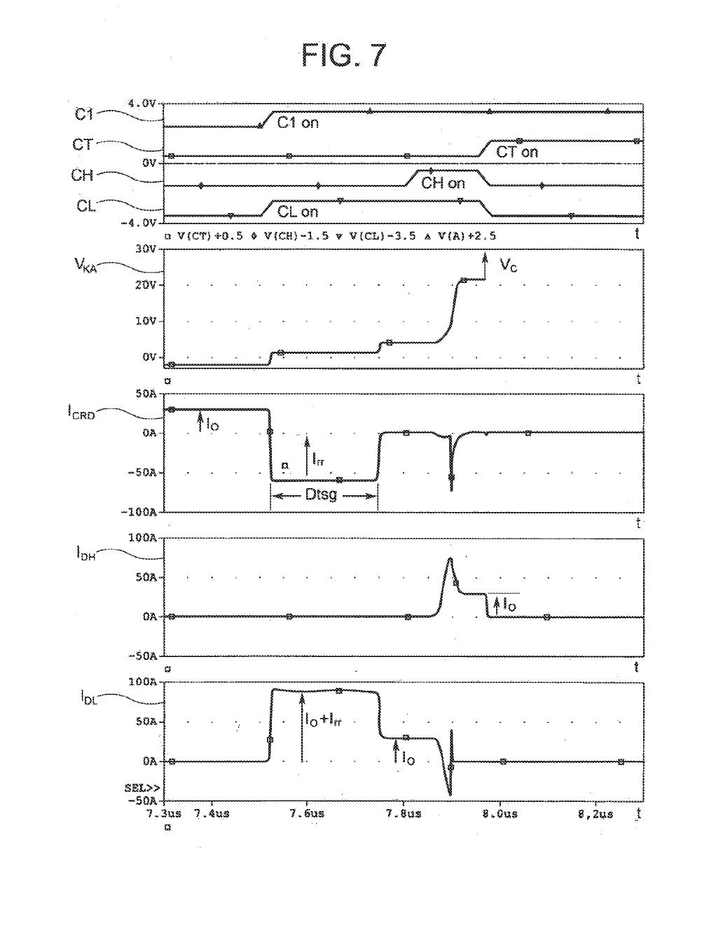

FIG. 7 is a series of diagrams illustrating, as a function of the time t shown on the horizontal axis, exemplary ideal variations of electrical quantities in the switching cell of FIG. 6;

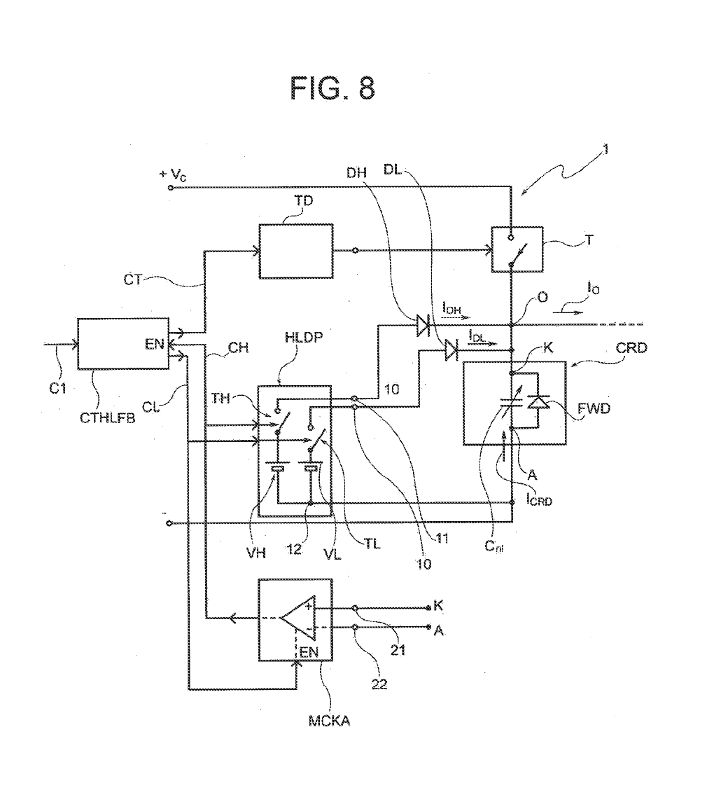

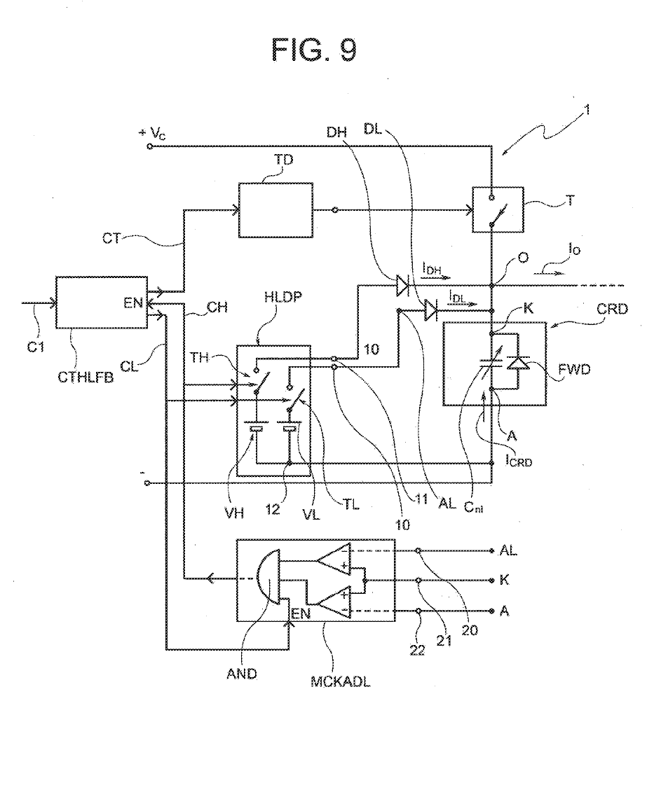

FIGS. 8 and 9 are further circuit diagrams, partially in block form, of unidirectional switching cells with optimized control according to the invention;

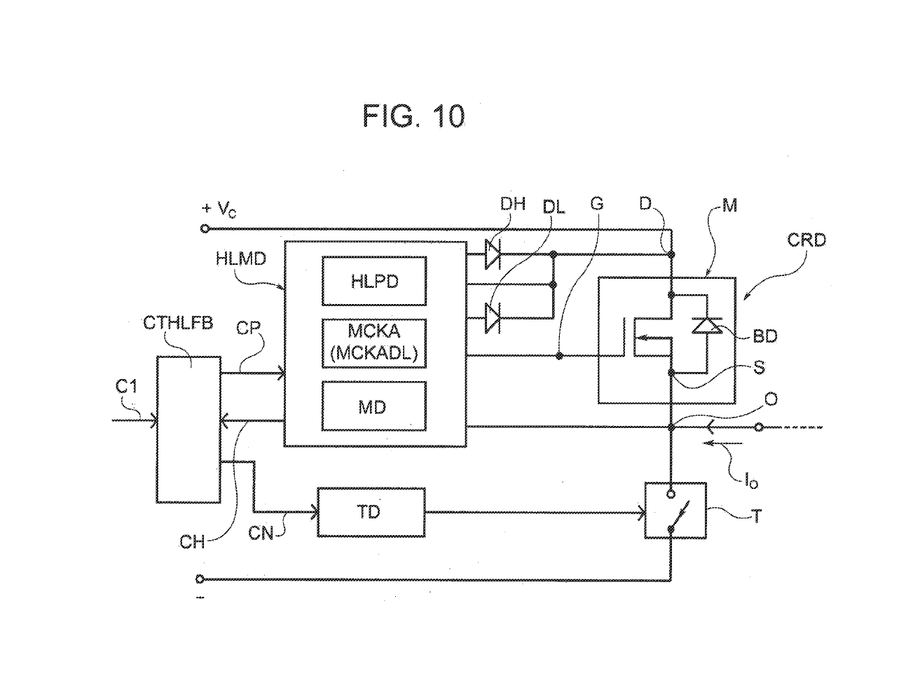

FIG. 10 is a circuit diagram, partially in block form, of a unidirectional switching cell according to the invention which uses a MOSFET as an SR, and in which the circuits are integrated into a single circuit, comprising the driving of the MOSFET operating as an SR;

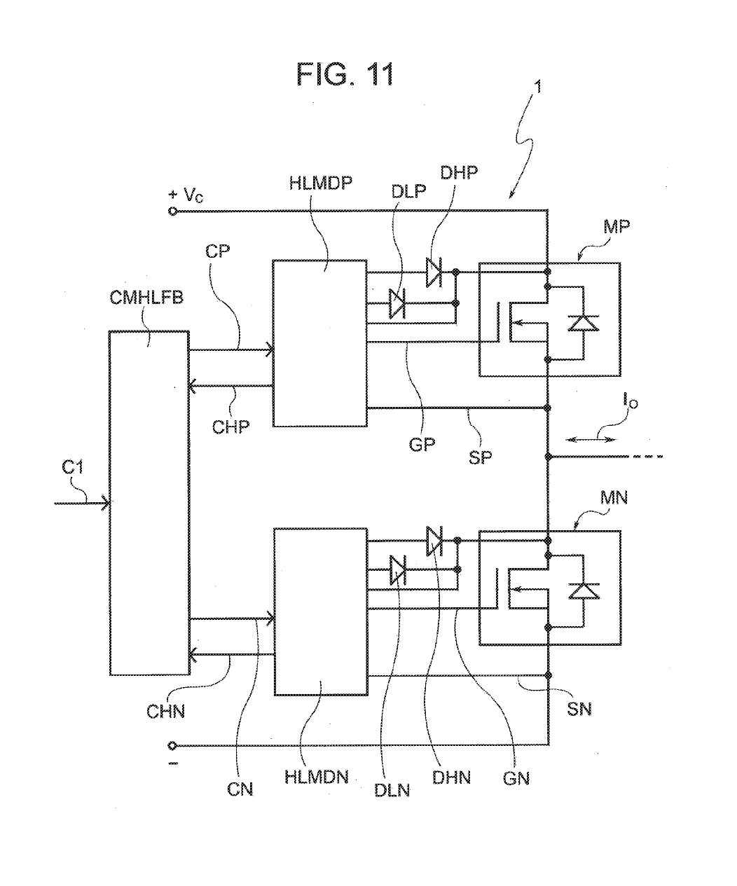

FIG. 11 is a circuit diagram, partially in block form, of a bidirectional switching cell according to the invention which uses two MOSFETs, both capable of operating as SRs because of the integration of the circuits according to the invention in the corresponding driver circuits;

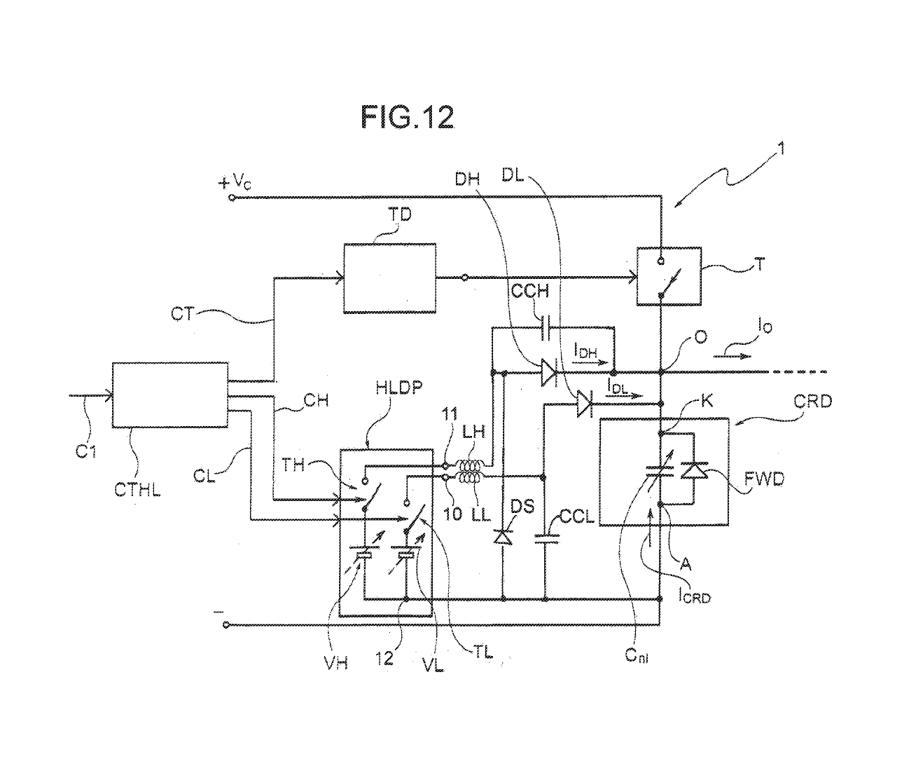

FIG. 12 is a circuit diagram of another switching cell according to the invention; and

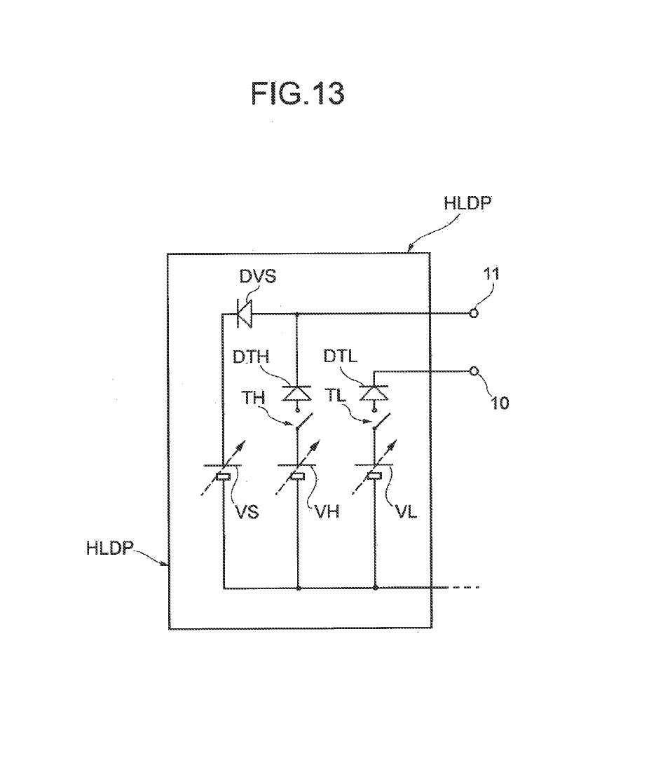

FIG. 13 is a circuit diagram showing an embodiment of a voltage generator circuit which can be used in the switching cell of FIG. 12.

With reference to FIG. 6, a unidirectional current controlled switching cell 1 according to the invention comprises a switch T, which can be for example a bipolar or field effect transistor, controlled by a driver circuit TD, and a current recirculation device CRD, of any type, exhibiting the dynamic phenomena of a power recirculation diode FWD, and the non-linear capacitive phenomena typical of power semiconductors, represented by a capacitor Cₙₗ having a non-constant capacitance. The cathode of the current recirculation diode FWD is indicated by K, while its anode is indicated by A.

A low-voltage generator circuit, indicated as a whole by HLPD, is connected across the recirculation device CRD through two high-voltage diodes DH and DL, connected to CRD, and particularly to its diode FWD, in such a way that all three diodes have one common homologous terminal, while the other terminals of the diodes DH and DL are connected to the circuit HLPD.

In FIG. 6, the common terminal is the cathode (K). The anodes of the diodes DH and DL are therefore connected to the circuit HLPD through two terminals indicated by 11 and 10, respectively, while the anode of the diode FWD is connected to the circuit HLPD through a terminal 12.

The diode DL is a diode designed to conduct pulsed currents which are much higher than the output current I_{O} of the cell 1, since it has to supply the charge for the reverse recovery of the diode FWD with the smallest possible drops. Thus the voltage of the generator VL is minimized, this generator being designed to supply the reverse recovery charge of FWD via the closure of the low-voltage controlled switch TL. In particular, therefore, DL must be a single diode with a large area and must be of the semiconductor junction type, with corresponding non-negligible phenomena of reverse recovery and parasitic capacitance, although these phenomena are smaller than those of the diode FWD.

This saving of cost and energy is made possible by the subsequent operation of the diode DH, made for example in the form of a smaller Schottky diode for high voltage, or by a series composed of a plurality of ultra-fast low-voltage diodes, with negligible phenomena of reverse recovery and parasitic capacitance in both cases. The diode is designed to apply the voltage of the generator VH, which is also positive, between the terminals K and A of FWD, this voltage being much higher than the voltage generated by V_{L}, to supply the parasitic charge of Cₙₗ in CRD, thus simultaneously supplying the reverse recovery of the diode DL, although this is only brief, and its parasitic capacitance.

In order to perform this series of operations, the circuit HLPD is controlled by means of signals CH and CL to close the low-voltage switches TH and TL respectively. These commands are timed by a control unit CTHL, which also generates the control signal CT for the driver TD of the power switch T of the cell, on the basis of a command C1 which determines the state of the whole of the cell 1, and which is supplied, for example, by a pulse width modulator PWM which is not shown.

With reference to the circuit of FIG. 6, FIG. 7 shows exemplary variations in time of these commands, and the consequent exemplary waveforms of essential electrical variables following a leading edge of the control signal C1 which starts the sequence resulting in the leading edge of the command CT to close the switch T.

Before this leading edge of C1, the voltage V_{KA} across the current recirculation device CRD has a slightly negative value, visible in FIG. 7, equal to the conduction drop of CRD, or of FWD, corresponding to the conduction of the output current I_{O} seen in the graph of I_{CRD}.

The sequence shown in FIG. 7 is essential:
at the leading edge of C1, the command CL closes the switch TL, so as to cut off FWD and force its reverse recovery;
during the period of delay Dtsg in the cut-off of FWD, called the “storage time”, FWD remains in the preceding state of high electrical conductivity, and the generator VL supplies through the DL the current I_{DL}, equal to the sum of the reverse current Iᵣᵣ in FWD, visible in the graph of I_{CRD}, and the output current I_{O};
the storage charge, supplied during the storage time Dtsg, is equal to Iᵣᵣ*Dtsg;
for the purposes of the invention, it would be optimal to close the switch TH immediately at the end of the storage time, whereas in FIG. 7 there is a time interval of delay in the closure of TH, which prevents the supply, even if only partial, of the reverse recovery charge from the generator VH;
the closure of the switch TH is therefore controlled by the signal CH, in order to apply the highest voltage generated by VH to the CRD through the diode DH, thus supplying the non-linear charge of its parasitic capacitor Cₙₗ;
at the same time, this closure of TH also supplies the cut-off charge of the diode DL, including the charge for its reverse recovery, finally leading to the reverse voltage value equal to the difference between the voltages of the two generators VH and VL;
finally, the controlled switch T of the cell is closed, with practically no opposing parasitic phenomenon, since the diode DH is a diode without reverse recovery and with negligible parasitic capacitance, partially due to its smaller semiconductor area.

Therefore the operation to close the switch T of the cell takes place in a practically non-dissipative way, the absorption of energy by the circuit HLPD being as follows:
a high charge is absorbed from the generator VL, this charge being equal to the integral of the current I_{DL}, which has a very high value (Iᵣᵣ+I_{O}) in the storage time, and has the value I_{O} in the remainder of the period of delay in the closure of TH, but the absorbed energy EL is reduced because of the very low voltage of VL (EL=V_{L}* [symbol] I_{DL} dt);
a normally smaller charge is absorbed from the generator VH, this charge being equal to the value of the integral of I_{DH}, but the absorbed energy can be greater than EL because of the higher voltage of VH (E_{H}=V_{H}* [symbol] I_{H} dt).

FIG. 8 is a diagram of another switching cell 1 according to the invention, which provides the functionality previously described and represented in the graphs of FIG. 7, by means of a further unit MCKA for monitoring and comparing the voltage between the terminals K and A of the current recirculation device CRD, or of FWD, this unit being capable of generating the control signal CH in feedback mode, in other words immediately and exactly at the end of the storage time interval Dtsg, or on the cessation of the state of high electrical conductivity of CRD, in other words of its diode FWD.

The diagram of FIG. 8 is derived from that of FIG. 6, the only difference being the replacement of the control unit CTHL by a unit CTHLFB, the signal CH, for controlling TH, being directly generated in this case in feedback mode by the unit MCKA for monitoring and comparing the voltage V_{KA}. The control signal CL for controlling the switch TL, generated by the unit CTHLFB, is also sent to the unit MCKA as an enabling and final cut-off signal of the command CH for closing TH, generated locally by the voltage comparator of MCKA which is enabled in this way by CL.

The comparison of the voltage V_{KA} with a predetermined threshold is ideally sufficient to determine the end of the storage time, because the reverse current falls from a very high level to practically zero, thus greatly reducing the voltage drop in the series circuit VL+TL+DL, so that the voltage V_{KA} reaches its maximum value in a discontinuous way, for example as shown in FIG. 7, during this first step of supply from the generator VL. Thus optimal efficiency and maximum operating reliability are obtained, since the storage time is highly dependent on the temperature and on the output current I_{O} as well as on the reverse recovery current Iᵣᵣ.

In order to achieve maximum efficiency, with reference to FIG. 8, according to the invention the command CH generated locally by MCKA is also transferred in feedback mode to the control unit CTHLFB, which uses it as an enabling signal for generating the leading edge of the signal CT, thus terminating the sequence of switching operations with the closure of the switch T of the cell, which reverse-biases the diode DH and causes the cessation of any energy consumption by the low-voltage circuit HLPD.

With reference to FIG. 7, the delay between the leading edge of CH and the trailing edge of CT can be deliberate or simply produced by the series of delays in the signal transmission chain (practically certain to occur with galvanic isolation); in any case, the time concerned is very short and, above all, can be predetermined. This is because the quantity of charge to be supplied to CRD, or to its non-constant capacitance Cₙₗ, is practically constant, in other words practically independent of temperature and current.

In order to increase reliability further, with reference to the diagram of FIG. 8, according to the invention, in the diagram of FIG. 9 the measurement of the end of the storage time is carried out in a theoretically redundant way by a unit MCKADL, which also measures and compares the current conducted by the diode DL, which must be not greater than the output current I_{O} of the cell in order to improve the certainty of the end of the storage time. In particular, in the diagram of FIG. 9 the measurement of the current I_{DL} in the diode DL is carried out more simply as the measurement of the voltage drop between its anode AL (the input terminal 20 of MCKADL) and its cathode which coincides with the cathode K (terminal 21) of the recirculation device CRD. This is because DL is an ultra-fast junction device and its voltage drop can therefore represent an accurate measurement of current, which may also have little dependence on temperature, at the high threshold current level required according to the invention.

The two comparators and the subsequent logical AND function, which generates the command CH, are illustrated schematically in the unit MCKADL, this logical AND function having three inputs to receive the signal CL, used as the enabling signal for the generation of the signal CH.

Any of the preceding solutions is applicable to a MOSFET, indicated by M in FIG. 10, which can be used as an SR and therefore as a current recirculation device CRD, with the sole addition of its driver circuit MD, of a known type, which controls the gate-source voltage of this MOSFET M. The whole arrangement, indicated by HLMD, of the driver circuit MD and of the circuits according to the invention, in other words of the circuit HLPD, which supplies the diodes DH and DL, together with MCKA or MCKADL, is a homogeneous assembly of low-voltage circuits which can therefore be easily integrated. The complete functionality provided according to the invention is therefore shown schematically as comprising the driver and measurement circuit HLMD of the MOSFET SR and of the diodes DH and DL, differentiated in the quantity and quality of semiconductors used, but capable as a whole of withstanding the same nominal voltage of the MOSFET SR as that present in the cut-off according to the invention.

In FIG. 10, use is made, in particular, of an N-channel MOSFET, whose source S is the reference terminal coinciding with the anode of its body diode BD; therefore the common connection, according to the invention, of the diodes DH and DL is that of the respective cathodes with the cathode D of the body diode BD of the N-channel MOSFET. The command CP at the input of HLMD is supplied by a control circuit PWM known in itself, which can use the signal CH, when generated internally by the measurement and comparison unit MCKA or MCKADL according to the invention, to synchronize in the best way the switching of the controlled switch which is combined with the MOSFET SR used as a CRD in a switching cell.

FIG. 11 shows schematically a bidirectional switching cell 1 according to the invention which uses two N-channel MOSFETs, each having a driver circuit HLMDP and HLMDN, and diodes DHP, DLP and DHN, DLN capable, according to the invention, of making the best use of the MOSFETs which are used as SRs and therefore as recirculation devices, and also as controlled switches according to the prior art. In use, depending on the direction of the current I_{O} entering or leaving the common terminal O of the cell 1, one of the aforesaid MOSFETs acts as a power switch and the other acts as a recirculation device.

In FIG. 11 the subscripts P and N are added for the MOSFETs, and for the circuits according to the invention connected thereto, which are, respectively, connected to the positive and the negative pole of the supply voltage V_{C} of the switching cell 1.

In particular, in FIG. 11 use is made of a switching unit CMHLFB capable of synchronizing in feedback mode the closing of the MOSFET acting as a controlled switch, as a function of the signal CH generated by the circuit HLMD connected to the MOSFET acting as an SR or as a recirculation device.

In the two possible cases, depending on the sign of the output current I_{O}:
I_{O} outgoing implies that MP is a controlled switch and MN is the recirculation device; CN is the “negative” of C1, and CP coincides with C1 but with a delay on the leading edge of CP, as this is synchronized according to the invention with the leading edge of CHN;
I_{O} incoming implies that MN is a controlled switch and MP is the recirculation device; CP coincides with C1, and CN coincides with the “negative” of C1, but with a delay on the leading edge of CN, as this is synchronized according to the invention with the leading edge of CHP.

FIG. 12 shows a variant embodiment of the switching cell according to the invention. In this drawing, parts and elements described previously have again been given the alphanumeric references used previously.

In the variant shown in FIG. 12, respective inductances LL and LH are present between the voltage sources VL and VH and the corresponding first and second diodes DL and DH. These inductances LL and LH can be simply the “parasitic” inductances of the connections, and/or can be made in the form of inductances interposed between the voltage sources VL, VH and the diodes DL, DH.

A first and a second capacitor CL and CH are connected, respectively, in parallel to the branch of the circuit which includes the diode DL and the recirculation device CRD, and in parallel to the diode DH.

A further diode DS is connected in parallel with the circuit branch including the diode DH and the recirculation device CRD. In particular, this diode DS has its cathode connected to the anode of the diode DH in FIG. 12, representing the case in which the common terminal of FWD, DH and DL is the cathode.

Overall, FIG. 12 represents a further solution according to the invention, which is optimal in all cases in which the dynamic of the injected currents is determined by inductances which are parasitic on the connections themselves and/or deliberately provided.

In these cases, the energy accumulated in the inductances LH and LL provides a further enhancement of the efficiency of switching in combination with the capacitors CCH and CCL which are provided appropriately according to the invention.

The current in the inductance LL must be able to reach values much higher than the switched current I_{O} in order to force the opening of the recirculation device CRD. The capacitive branch CCL is therefore designed so as to limit the derivative of the voltage resulting from the actual opening of FWD to design values. In particular, the capacitive branch CCL allows the use of simpler and more efficient junction diodes which exhibit discontinuous (“snappy”) behaviour at the end of the storage period.

Conversely, the energy accumulated in LH provides an enhancement of the efficiency of the closing operation of T, during which T must conduct a reduced current, equal to the difference between the output current and the current IDH conducted by LH. This difference can be reliably brought close to zero by closing T when the voltage across CRD exceeds the voltage of the generator VH, which effectively forces the voltage rise in CRD because of the presence of the capacitive branch CCL, which is also provided to impede the voltage rise in CRD as a result of the forcing, which may be excessive in current, which is created by the circuit supplied by the generator VL. Thus the voltage transition across CRD can be created in an optimal way as a monotonic function in time and with an increasing derivative, minimizing the stress on CRD and the efficiency of the completion of its opening, for diodes FWD of either the snappy or the soft type.

The diode DL contributes to the voltage transition with its reverse recovery, which automatically provides the initial connection of the CCL branch in parallel with CRD, which terminated at the end of the storage of DL. This makes it even more advantageous to make DL in the form of junction diodes, which are more efficient and economical.

A further function of the capacitive branch CCL according to the invention is provided when the charge accumulated in the transition of CRD is naturally maintained and not discharged. In this way, the voltage of the branch CCL is usefully discharged by the switched current lo in the next opening operation of T, thus limiting the derivative of opening voltage at T to the point where the excess voltage typical of turn-off is cancelled.

The capacitance CCH is provided for multiple functions according to the invention. The closure of T is followed by the cut-off of the diode DH, which comprises the necessary conduction of a reverse cut-off current, for the reverse recovery of junction diodes, or simply for charge displacement in Schottky diodes. The capacitance CCH is therefore useful or necessary for limiting the derivative of voltage resulting from the cut-off of DH.

However, the presence of CCH enables two other important functions to be provided in a controllable way according to the invention, as follows:
the reverse charge of DH and the charge displacement of CCH form a source of supply of the generator unit HLDP, which can be designed to benefit therefrom in a controlled way;
if this supply step is suitably regulated, the capacitor CCH is usefully charged at the end of the turn-on of T, operating at the successive turn-off of T as a capacitive branch in parallel through the diode DS, which limits the derivative of opening voltage and therefore of the corresponding switching losses.

FIG. 13 shows the conceptual diagram of an advantageous embodiment of the voltage generator circuit HDLP for a switching cell 1 according to FIG. 12.

In FIG. 13 also, elements already described have again been given the same alphanumeric references as those used previously.

FIG. 13 defines the essential characteristics required for useful regulation according to the invention of all the flows of charge in the HLDP unit. The diodes DTH and DTL connected in series with the switches TH and TL indicate that the generators VH and VL in series with them can be simply discharged for the controlled forcing of the opening of CRD according to the invention. This is because the voltages of both are usefully low with respect to the switched voltage Vc and it would therefore be excessive and inefficient to allow the reverse conduction of DH and the charging of CCH directly in the generator VH.

In FIG. 13, according to the solution shown in FIG. 12, the branch composed of the generator VS with the corresponding diode DVS in series is therefore inserted, indicating that this generator VS can absorb current and energy solely from the reverse conduction of DH and from the charge of CCH. According to the objects of the invention, it can be asserted that the voltage of this generator VS must be greater than or equal to half of the switched voltage Vc; otherwise the charging transient of CCH would become unhelpfully excessive, in terms of both energy and the total time of the transient.

Overall, FIG. 13 shows the unit HLDP as a unit which is autonomous in energy terms, which is useful according to the invention. Therefore the generators VL, VH and VS, indicated appropriately as variable generators, can actually be made in the form of capacitor networks: VS can be a high-voltage capacitive accumulator from which the necessary energy is drawn to maintain the charge in the low-voltage capacitors forming the variable generators VH and VL. This regulation is responsible for some of the accuracy of the opening transient of CRD according to the invention, in combination with the time sequence of the closure of the switches TH and TL.

A further function is provided by the energy autonomy of the generator unit HLDP, according to FIG. 13. The energy absorbed by the two-terminal generators VH and VL, required for the opening of CRD according to the invention, is a monotonically increasing function of the switched current Io, while the energy which recharges the two-terminal circuit VS is a monotonic function of the variation of voltage across CCH at the end of the turn-on of T. Therefore the capacitive function of assistance to the turn-off of T, provided by CCH together with the diode DS, is autonomously progressive with the current. This intrinsic function according to the invention provides an ideal progression, in functional and energy terms, of the opening operation of T, thus complementing the result of the closing operation according to the invention.

Further specific functions can be provided with the solution shown in FIG. 12, as follows:
the inductance LH can conveniently be made in the form of a variable or saturable inductance to make the variation of function with the current Io more gradual, thus permitting the use of economical low-drop diodes (which are slower in reverse recovery) without an excessive recharging current;
the “H” type and “L” type charge injection circuits can be multiple, in order to apply all the effects according to the invention in a more accurate and progressive way, or multiple circuits with capacitive branches such as CCH and CCL can be provided;
the two-terminal voltage generator circuit VL can be made in the form of a simple capacitor charged between one switching operator and another at regulated low current according to the invention, and discharged in a pulsed but controlled way as a result of the presence of the inductance VL, which is generally fully provided by the inductive effects of the simple connections.

As regards the autonomous construction in energy terms of the unit HLDP according to FIG. 13, there are highly economical means for regulating the energy flow between the high voltage on the two-terminal capacitive circuit VS and the low voltage of the users which draw it from the two-terminal capacitive circuits VH and VL. In particular, a simple network of diodes and capacitors (in the quantity NC) enables the charging to be carried out at the voltage VS, and discharging at the voltage VS/NC. In other words, it is easy to provide a passive relation of the type VH=VS/NC.

Clearly, provided that the principle of the invention is retained, the forms of application and the details of construction can be varied widely from what has been described and illustrated purely by way of non-limiting example, without thereby departing from the scope of protection of the invention as defined by the attached claims

1. Controlled switching cell (1), wherein between the terminals of a supply source (2) supplying a d.c. voltage (V_{C}) there are connected a controlled power switch (T) and a current recirculation device (CRD) comprising a diode or a junction, between which there is defined a common terminal (O) of the cell (1);
the cell (1) being such that across the current recirculation device (CRD) there are connected controlled electric charge supply means (TL, VL, DL; TH, VH, DH) comprising
a first generator circuit (TL, VL, DL) for generating a low voltage, including a first d.c. voltage source (VL), an associated first controlled switch (TL), and a first diode (DL), the first generator circuit (TL, VL, DL) being adapted to supply an electric charge sufficient to cause the reverse-recovery of the current recirculation device (CRD);
the cell being characterized in that the controlled electric charge supply means further comprise
a second generator circuit (TH, VH, DH) for generating a higher voltage, including a second d.c. voltage source (VH), an associated second controlled switch (TH) and a second diode (DH), the second generator circuit (TH, VH, DH) being adapted to inject into the recirculation device (CRD) an amount of electric charge (Q_{D}) which varies in a non-linear manner as a function of the higher voltage, and also to deliver an amount of electric charge sufficient to cause the first diode (DL) to be cut off when the first controlled switch (TL) is closed.

2. Controlled switching cell according to claim 1, wherein the first diode (DL) is a semiconductor-junction diode, and the second diode (DH) is a Schottky diode or is formed from a plurality of diodes in series.

3. Switching cell according to claim 1, wherein the first and second diodes (DL, DH) each have a respective homologous terminal (cathode or anode) connected to the homologous terminal (K or A) of the diode or junction (FWD) of the current recirculation device (CRD).

4. Switching cell according to claim 1, comprising further control means (CTHL) designed to control in predetermined ways the controlled power switch (T) and the first and second controlled switches (TL, TH), in such a way that before the controlled power switch (T) is closed, the first switch (TL) is initially closed so as to cut off the diode or junction (FWD) of the current recirculation device (CRD), and subsequently, after a time interval longer than the storage time (Dtsg) of the diode or junction (FWD), the second switch (TH) is closed, and finally the controlled power switch (T) is closed.

5. Switching cell according to claim 4, wherein the control means (CTHLFB) are associated with comparison and monitoring means (MCKA) for comparing and monitoring the voltage (V_{KA}) across the current recirculation device (CRD, FWD), and wherein the control means (CTHLFB) are designed to enable the operation of the comparison and monitoring means (MCKA) simultaneously with the closing command for the first controlled switch (TL), and the comparison and monitoring means (MCKA) are designed to cause the switching of the second controlled switch (TH) as a function of the value of the voltage (V_{KA}) monitored across the current recirculation device (CRD, FWD).

6. Switching cell according to claim 5, wherein the comparison and monitoring means (MCKA) are further connected to an enabling input of the control means (CTHLFB), for delivering to the control means (CTHLFB) an enabling signal for closing the power switch (T).

7. Switching cell according to claim 6, wherein the comparison and monitoring means (MCKADL) are also designed to monitor the current flowing in the first diode (DL), and comprise enabling logic means (AND) adapted to allow the second controlled switch (TH) to be closed when both the voltage (V_{KA}) monitored across the current recirculation device (CRD, FWD) and the current in the first diode (DL) conform to predetermined conditions.

8. Switching cell according to claim 1, wherein the current recirculation device (CRD) comprises at least one MOSFET transistor with an associated body-diode (BD).

9. Switching cell according to claim 1, comprising two MOSFET transistors (MP, MN) with respective driving circuits (HLMDP, HLMDN) and respective first and second diodes (DLP, DHL; DLN, DHN); the driving circuits (HLMDP, HLMDN) being controlled by switching control means (CMHLFB) in such a way that, depending on whether the current (I_{O}) at the common terminal (O) of the cell (1) is incoming or outgoing, one of the MOSFET transistors (MP, MN) operates as a controlled power switch (CT), and the other of the MOSFET transistors (MP, MN) operates as a current recirculation device (CRD).

10. Switching cell according to claim 1, wherein the first and second generator circuits (TL, VL, DL, LL; TH, VH, DH, LH) comprise
first and second inductive means (LL, LH) respectively, between the respective voltage sources (VL, VH) and the corresponding first and second diode (DL, DH),
first and second capacitive means (CL, CH) connected, respectively, in parallel with the circuit branch including the first diode (DL) and the recirculation device (CRD) and in parallel with the second diode (DH); and wherein
a branch diode (DS) is connected in parallel with the circuit branch including the second diode (DH) and the recirculation device (CRD).
